(19) United States
(12) Patent Application Publication
(10) Pub. No.: US 2026/0344180 A1
(43) Pub. Date: Oct. 29, 2026

(54) ORGANIC LIGHT EMITTING DIODE AND ORGANIC LIGHT EMITTING DISPLAY DEVICE INCLUDING THE SAME

(71) Applicant: LG Display Co., Ltd., Seoul (KR)

(72) Inventors: Kwang-Jong KIM, Paju-si (KR); Do-Yeong SHIN, Paju-si (KR)

(21) Appl. No.: 19/661,256

(22) Filed: Apr. 28, 2026

(30) Foreign Application Priority Data
Apr. 29, 2025 (KR) 10-2025-0056554

(51) Int. Cl. H10K 50/19; H10K 50/15; H10K 59/80

(52) U.S. Cl. CPC H10K 50/19; H10K 50/156; H10K 59/873

(57) ABSTRACT

An organic light emitting diode includes first and second electrodes; a first emitting stack including a first hole transporting layer (HTL), a first hole auxiliary layer and a first emitting material layer (EML); a second emitting stack including a second HTL, a second hole auxiliary layer and a second EML; and a first charge generation layer between the first and second emitting stacks. The first EML includes first to third blue emitting layers. The second EML includes fourth to sixth blue emitting layers. A hole mobility of the first HTL is greater than that of the first hole auxiliary layer, and a hole mobility of the second HTL is greater than that of the second hole auxiliary layer. The hole mobility of the second hole auxiliary layer is greater than that of the first hole auxiliary layer.

### CROSS-REFERENCE TO RELATED APPLICATIONS

Pursuant to 35 U.S.C. § 119(a), the present application claims the benefit of an earlier filing date and right of priority to Korean Patent Application No. 10-2025-0056554 filed in the Republic of Korea on Apr. 29, 2025, the content of which is hereby incorporated by reference in its entirety.

### TECHNICAL FIELD

The present disclosure relates to a display device.

### BACKGROUND

With the increased development of large-area display devices, there is increased demand for flat display devices that can nonetheless achieve small space occupancy. Examples of flat display devices include liquid crystal (LC) display devices, organic light emitting display devices, and inorganic light emitting display devices.

For example, an organic light emitting display device includes an organic light emitting diode (OLED). In the OLED, holes from an anode and electrons from a cathode are combined to generate an exciton in an organic light emitting layer, and the exciton is transformed from an excited state to a ground state. As a result, light is emitted from the OLED.

However, OLEDs are often limited in emitting efficiency. Particularly, there is a significant limitation of emitting efficiency and lifespan in the blue emission of an OLED.

### SUMMARY

An aspect of the present disclosure is an organic light emitting diode, including a first electrode; a second electrode facing the first electrode; a first emitting stack positioned between the first and second electrodes and including a first hole transporting layer, a first hole auxiliary layer on the first hole transporting layer and a first emitting material layer on the first hole auxiliary layer; a second emitting stack positioned between the first emitting stack and the second electrode and including a second hole transporting layer, a second hole auxiliary layer on the second hole transporting layer and a second emitting material layer on the second hole auxiliary layer; and a first charge generation layer between the first and second emitting stacks, wherein the first emitting material layer includes a first blue emitting layer on the first hole auxiliary layer, a second blue emitting layer on the first blue emitting layer and a third blue emitting layer on the second blue emitting layer, wherein the second emitting material layer includes a fourth blue emitting layer on the second hole auxiliary layer, a fifth blue emitting layer on the fourth blue emitting layer and a sixth blue emitting layer on the fifth blue emitting layer, wherein a hole mobility of the first hole transporting layer is greater than a hole mobility of the first hole auxiliary layer, and a hole mobility of the second hole transporting layer is greater than a hole mobility of the second hole auxiliary layer, and wherein the hole mobility of the second hole auxiliary layer is greater than the hole mobility of the first hole auxiliary layer.

Another aspect of the present disclosure is an organic light emitting display device including a substrate; the above organic light emitting diode disposed over the substrate; and an encapsulation layer covering the organic light emitting diode.

It is to be understood that both the foregoing general description and the following detailed description are examples and explanatory and are intended to further explain the present disclosure as claimed.

### BRIEF DESCRIPTION OF THE DRAWINGS

FIG. 1 is a schematic view illustrating an example of an organic light emitting display device of the present disclosure.

FIG. 2 is a schematic circuit diagram of an example of an organic light emitting display device of the present disclosure.

FIG. 3 is a schematic cross-sectional view of an example of one pixel region of an organic light emitting display device according to a first implementation of the present disclosure.

FIG. 4 is a schematic cross-sectional view of an example of an organic light emitting display device according to the first implementation of the present disclosure.

FIG. 5 is a schematic cross-sectional view of an example of an OLED for an organic light emitting display device according to the first implementation of the present disclosure.

FIG. 6 is a schematic cross-sectional view of an example of an organic light emitting display device according to a second implementation of the present disclosure.

FIG. 7 is a schematic cross-sectional view of an example of an organic light emitting display device according to a third implementation of the present disclosure.

FIG. 8 is a schematic cross-sectional view of an example of an OLED of an organic light emitting display device according to the third implementation of the present disclosure.

FIG. 9 is a schematic cross-sectional view of an example of an OLED of an organic light emitting display device according to the first and second implementations of the present disclosure.

### DETAILED DESCRIPTION

Implementations of the present disclosure can provide an organic light emitting diode capable of providing an appropriate low-grayscale capacitance and high emitting efficiency, and an organic light emitting display device including the same.

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts may be added unless ‘only’ is used. When a component is expressed in the singular, cases including the plural are included unless specific statement is described.

The expression “at least one of a, b, and c” described throughout the specification can encompass ‘a alone’, ‘b alone’, ‘c alone’, ‘a and b’, ‘a and c’, ‘b and c’, or ‘all of a, b, and c’. The advantages and features of the present disclosure, and the methods for achieving them, will become apparent by referring to the implementations described in detail below together with the accompanying drawings.

In construing an element, the element is construed as including an error or tolerance range although there is no explicit description of such an error or tolerance range.

In describing a position relationship, for example, when a position relation between two parts is described as, for example, “on”, “over”, “under”, and “next”, one or more other parts may be disposed between the two parts unless a more limiting term, such as “just” or “direct(ly)” is used.

In describing a time relationship, for example, when the temporal order is described as, for example, “after”, “subsequent”, “next”, and “before”, a case that is not continuous may be included unless a more limiting term, such as “just”, “immediate(ly)”, or “direct(ly)” is used.

The area, length, or thickness of each component described in the specification is illustrated for convenience of explanation, and the present disclosure is not necessarily limited to the area and thickness of the illustrated component.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Unless otherwise defined, all terms (including technical and scientific terms) used herein have the same meaning as commonly understood by one of ordinary skill in the art to which example implementations belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these implementations may be provided so that this disclosure may be sufficiently thorough and complete to assist those skilled in the art to fully understand the scope of the present disclosure. Furthermore, the present disclosure is only defined by scopes of claims.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Without specific description, a transistor constituting the pixel circuit of the present disclosure may include at least one of an oxide thin film transistor (Oxide TFT), an amorphous silicon TFT (a-Si TFT), and a low temperature poly silicon (LTPS) TFT.

Reference will now be made in detail to some of the examples and preferred implementations, which are illustrated in the accompanying drawings.

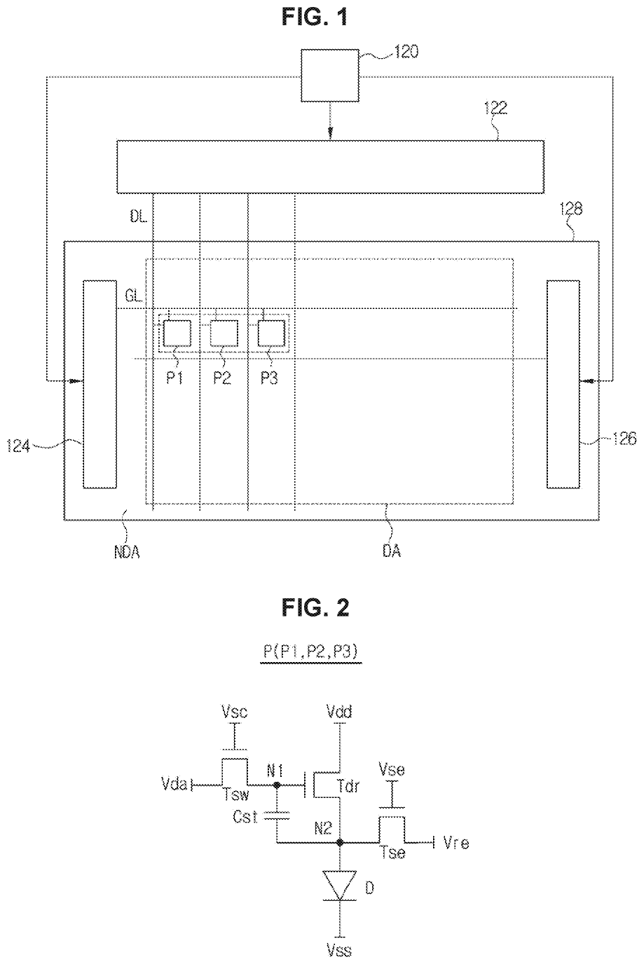

FIG. 1 is a schematic view illustrating an organic light emitting display device of the present disclosure, and FIG. 2 is a schematic circuit diagram of an organic light emitting display device of the present disclosure.

As shown in FIGS. 1 and 2, an organic light emitting display device according to an implementation of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal and a gate control signal using an image signal and a plurality of timing signals including a data enable signal, a horizontal synchronization signal, a vertical synchronization signal and a clock signal transmitted from an external system. The timing controlling unit 120 transmits the image data and the data control signal to the data driving unit 122, and transmits the gate control signal to the first and second gate driving units 124 and 126.

The data driving unit 122 generates a data signal (a data voltage) Vda using the image data and the data control signal transmitted from the timing controlling unit 120 and transmits the data signal Vda to a data line DL of the display panel 128.

The first and second gate driving units 124 and 126 generate a gate signal (a gate voltage) Vsc and Vse using the gate control signal transmitted from the timing controlling unit 120 and applies the gate signal Vsc and Vse to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel region P.

Although the first and second gate driving units 124 and 126 are disposed in both side portions of the display panel 128 in the implementation of FIG. 1, one gate driving unit may be disposed in one side portion of the display panel 128 in another implementation.

The display panel 128 includes a display area DA at a central portion thereof and a non-display area NDA surrounding the display area DA. The display panel 128 displays an image using the gate signal Vsc and Vse and the data signal Vda. In the display panel 128, a plurality of gate lines GL and a plurality of data lines DL cross each other to define a pixel region P including first, second and third pixel regions P1, P2 and P3. For example, the first to third pixel regions P1, P2 and P3 may correspond to blue, green and red colors, respectively.

Each of the first to third pixel regions P1, P2 and P3 may include a plurality of transistors such as a switching transistor Tsw, a driving transistor Tdr and a sensing transistor Tse, a storage capacitor Cst and an organic light emitting diode D.

Although the switching transistor Tsw, the driving transistor Tdr and the sensing transistor Tse may have a negative type in the implementation of FIG. 2, at least one of the switching transistor Tsw, the driving transistor Tdr and the sensing transistor Tse may have a positive type in another implementation.

The switching transistor Tsw is switched according to a scan signal Vsc through the gate line GL to transmit a data signal Vda to a first node N1.

The driving transistor Tdr is switched according to a voltage of the first node N1 to transmit a high level signal (high level voltage) Vdd to a second node N2.

The sensing transistor Tse is switched according to a sensing signal (sensing voltage) Vse to transmit a reference signal (reference voltage) Vre to the second node N2 or transmit a voltage of the second node N2 to a reference line.

The storage capacitor Cst keeps the data signal Vda supplied to the first node N1 for one frame and stores a threshold voltage Vth of the driving transistor Tdr.

A first capacitor electrode of the storage capacitor Cst is connected to the first node N1, and a second capacitor electrode of the storage capacitor Cst is connected to the second node N2.

The organic light emitting diode D emits a light of a luminance proportional to a current of the driving transistor Tdr.

An anode of the organic light emitting diode D is connected to the second node N2, and a cathode of the organic light emitting diode D is connected to a low level power line to receive a low level signal (low level voltage) Vss.

The organic light emitting diode D may display an image having a luminance corresponding to the image data according to a driving of pixel circuits of the first to third pixel regions P1, P2 and P3.

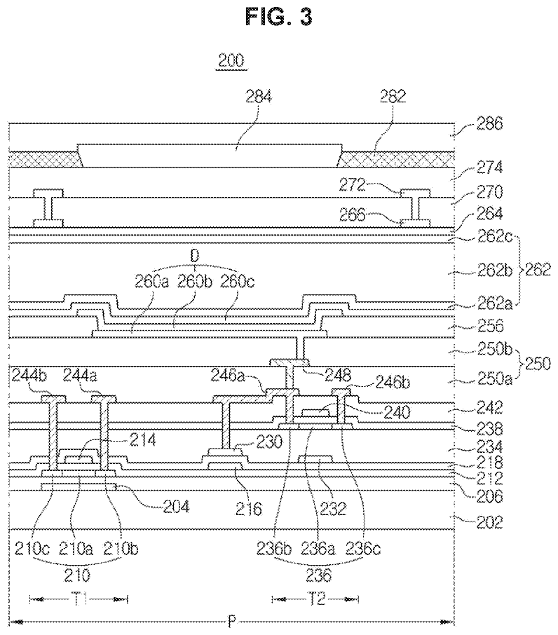

FIG. 3 is a schematic cross-sectional view of one pixel region of an organic light emitting display device according to a first implementation of the present disclosure.

As shown in FIG. 3, an organic light emitting display device 200 includes a substrate 202 including a pixel region P and an OLED D over the substrate 202.

The substrate 202 may be a glass substrate or a plastic substrate. For example, the substrate 202 may be one of polyimide (PI) substrate, polyethersulfone (PES) substrate, polyethylenenaphthalate (PEN) substrate, polyethylene terephthalate (PET) substrate and polycarbonate (PC) substrate.

In an aspect of the present disclosure, the substrate 202 may have a triple-layered structure including a first polyimide layer, a second polyimide layer and an interlayer inorganic layer between the first and second polyimide layers. The interlayer inorganic layer may be formed of an inorganic insulating material, e.g., silicon oxide or silicon nitride.

A first light-shielding pattern 204 is disposed on the substrate 202. The light through the substrate 202 can be blocked by the first light-shielding pattern 204. For example, the first light-shielding pattern 204 may be formed of a metallic material, e.g., molybdenum (Mo), aluminum (Al), chromium (Cr), gold (Au), titanium (Ti), nickel (Ni), neodymium (Nd), copper (Cu) or their alloys, and may have a single-layered structure or a multi-layered structure.

A first buffer layer 206 covering the first light-shielding pattern 204 is disposed on the substrate 202. The first buffer layer 206 may serve to block external moisture and/or oxygen. For example, the first buffer layer 206 may be formed of an inorganic insulating material, e.g., silicon oxide or silicon nitride, and may have a single-layered structure or a multi-layered structure.

A first semiconductor layer 210 corresponding to the first light-shielding pattern 204 is disposed on the first buffer layer 206. The first semiconductor layer 210 may include one of a polycrystalline semiconductor material, an amorphous semiconductor material and an oxide semiconductor material. When the first light shielding pattern 204 and the first buffer layer 206 are omitted, the first semiconductor layer 210 may be directly disposed on the substrate 202.

In an aspect of the present disclosure, the first semiconductor layer 210 may be formed of a polycrystalline semiconductor material, e.g., polycrystalline silicon. The first semiconductor layer 210 may include a first channel region 210a, a first source region 210b at one side of the first channel region 210a and a first drain region 210c at the other side of the first channel region 210a. Impurities may be doped into the first source region 210b and first drain region 210c.

A first gate insulating layer 212 covering the first semiconductor layer 210 is disposed over the first buffer layer 206. For example, the first gate insulating layer 212 may be formed of an inorganic insulating material, e.g., silicon oxide or silicon nitride, and may have a single-layered structure or a multi-layered structure.

A first gate electrode 214 corresponding to the first channel region 210a of the first semiconductor layer 210 is disposed on the first gate insulating layer 212. In addition, a first capacitor electrode 216, which is spaced apart from the first gate electrode 214, is disposed on the first gate insulating layer 212.

The first gate electrode 214 and the first capacitor electrode 216 may be disposed at the same layer and formed of the same material. For example, each of the first gate electrode 214 and the first capacitor electrode 216 may be formed of a metallic material, e.g., Mo, Al, Cr, Au, Ti, Ni, Nd, Cu or their alloys, and may have a single-layered structure or a multi-layered structure.

A first interlayer insulating layer 218 covering the first gate electrode 214 and the first capacitor electrode 216 is disposed on the first gate insulating layer 212. For example, the first interlayer insulating layer 218 may be formed of an inorganic insulating material, e.g., silicon oxide or silicon nitride, and may have a single-layered structure or a multi-layered structure.

A second capacitor electrode 230 corresponding to the first capacitor electrode 216 and a second light shielding pattern 232 spaced apart from the second capacitor electrode 230 are disposed on the first interlayer insulating layer 218.

The second capacitor electrode 230 and the second light shielding pattern 232 may be disposed at the same layer and formed of the same material. For example, each of the second capacitor electrode 230 and the second light shielding pattern 232 may be formed of a metallic material, e.g., Mo, Al, Cr, Au, Ti, Ni, Nd, Cu or their alloys, and may have a single-layered structure or a multi-layered structure.

A second interlayer insulating layer 234 covering the second capacitor electrode 230 and the second light shielding pattern 232 is disposed on the first interlayer insulating layer 218. The second interlayer insulating layer 234 may serve to block external moisture and/or oxygen. For example, the second interlayer insulating layer 234 may be formed of an inorganic insulating material, e.g., silicon oxide or silicon nitride, or an organic insulating material, e.g., photo-acryl or benzocyclobutene (BCB), and may have a single-layered structure or a multi-layered structure.

A second semiconductor layer 236 corresponding to the second light shielding pattern 232 is disposed on the second interlayer insulating layer 234. The second semiconductor layer 236 may include one of a polycrystalline semiconductor material, an amorphous semiconductor material and an oxide semiconductor material.

In an aspect of the present disclosure, the second semiconductor layer 236 may be formed of an oxide semiconductor material, e.g., indium-gallium-zinc oxide (IGZO), zinc oxide (ZnO), tin oxide (SnO2), copper oxide (Cu2O), nickel oxide (NiO), indium-tin-zinc oxide (ITZO) or indium-aluminum-zinc oxide (IAZO). The second semiconductor layer 236 may include a second channel region 236a, a second source region 236b at one side of the second channel region 236a and a second drain region 236c at the other side of the second channel region 236a. Impurities may be doped into the second source region 236b and the second drain region 236c.

A second gate insulating layer 238 covering the second semiconductor layer 236 is disposed over the second interlayer insulating layer 234. For example, the second gate insulating layer 238 may be formed of an inorganic insulating material, e.g., silicon oxide or silicon nitride, and may have a single-layered structure or a multi-layered structure.

A second gate electrode 240 corresponding to the second channel region 236a of the second semiconductor layer 236 is disposed on the second gate insulating layer 238. For example, the second gate electrode 240 may be formed of a metallic material, e.g., Mo, Al, Cr, Au, Ti, Ni, Nd, Cu or their alloys, and may have a single-layered structure or a multi-layered structure.

A third interlayer insulating layer 242 covering the second gate electrode 240 is disposed on the second gate insulating layer 238. For example, the third interlayer insulating layer 242 may be formed of an inorganic insulating material, e.g., silicon oxide or silicon nitride, and may have a single-layered structure or a multi-layered structure.

A first source electrode 244a, a first drain electrode 244b, a second source electrode 246a and a second drain electrode 246b are disposed on the third interlayer insulating layer 242.

The first source electrode 244a and the first drain electrode 244b are respectively connected to the first source region 210b and the first drain region 210c via contact holes through the third interlayer insulating layer 242, the second gate insulating layer 238, the second interlayer insulating layer 234, the first interlayer insulating layer 218 and the first gate insulating layer 212. The first source electrode 244a is connected to the first capacitor electrode 216 via a contact hole through the third interlayer insulating layer 242, the second gate insulating layer 238, the second interlayer insulating layer 234 and the first interlayer insulating layer 218.

The second source electrode 246a and the second drain electrode 246b are respectively connected to the second source region 236b and the second drain region 236c via contact holes through the third interlayer insulating layer 242 and the second gate insulating layer 238. The second source electrode 246a is connected to the second capacitor electrode 230 via a contact hole through the third interlayer insulating layer 242, the second gate insulating layer 238 and the second interlayer insulating layer 234.

The first source electrode 244a, and the first drain electrode 244b, second source electrode 246a and the second drain electrode 246b may be disposed at the same layer and formed of the same material. For example, each of the first source electrode 244a, and the first drain electrode 244b, second source electrode 246a and the second drain electrode 246b may be formed of a metallic material, e.g., Mo, Al, Cr, Au, Ti, Ni, Nd, Cu or their alloys, and may have a single-layered structure or a multi-layered structure.

The first semiconductor layer 210, the first gate electrode 214, the first source electrode 244a and the first drain electrode 244b constitute a first TFT T1, and the second semiconductor layer 236, the second gate electrode 240, the second source electrode 246a and the second drain electrode 246b constitute a second TFT T2. For example, the first TFT T1 may be a switching TFT, and the second TFT T2 may be a driving TFT. The first capacitor electrode 216 and second capacitor electrode 230 constitute a storage capacitor.

The organic light emitting display device 200 of the present disclosure includes the first and second TFTs T1 and T2. Each of the first semiconductor layer 210 of the first TFT T1 and the second semiconductor layer 236 of the second TFT T2 may include one of a polycrystalline semiconductor material, an amorphous semiconductor material and an oxide semiconductor material, and at least one of the first semiconductor layer 210 of the first TFT T1 and the second semiconductor layer 236 of the second TFT T2 may include the oxide semiconductor material. In an aspect of the present disclosure, the first semiconductor layer 210 of the first TFT T1 may be formed of the polycrystalline semiconductor material, e.g., polycrystalline silicon, and the second semiconductor layer 236 of the second TFT T2 may be formed of the oxide semiconductor material.

In FIG. 3, the first gate electrode 214, the first source electrode 244a and the first drain electrode 244b are disposed over the first semiconductor layer 210, and the second gate electrode 240, the second source electrode 246a and the second drain electrode 246b are disposed over the second semiconductor layer 236. Namely, each of the first and second TFTs T1 and T2 have a coplanar structure. Alternatively, in each of the first and second TFTs T1 and T2, a gate electrode may be disposed under the semiconductor layer, and the source and drain electrode may be disposed on or over the semiconductor layer. Namely, each of the first and second TFTs T1 and T2 may have an inverted-staggered structure.

A planarization layer 250 covering the first source electrode 244a, the first drain electrode 244b, the second source electrode 246a, and the second drain electrode 246b is disposed on the third interlayer insulating layer 242. The planarization layer 250 may be formed of an organic insulating material, e.g., photo-acryl or BCB.

The planarization layer 250 may include a lower planarization layer (e.g., a first planarization layer) 250a on the first source electrode 244a, the first drain electrode 244b, the second source electrode 246a, and the second drain electrode 246b and an upper planarization layer (e.g., a second planarization layer) 250b on the lower planarization layer 250a.

A connection electrode 248 corresponding to the second source electrode 246a is disposed on the lower planarization layer 250a. The connection electrode 248 may be connected to the second source electrode 246a through a contact hole in the lower planarization layer 250a. For example, the connection electrode 248 may be formed of a metallic material, e.g., Mo, Al, Cr, Au, Ti, Ni, Nd, Cu or their alloys, and may have a single-layered structure or a multi-layered structure.

The upper planarization layer 250b is disposed on the lower planarization layer 250a to cover the connection electrode 248, and a first electrode 260a is disposed on the upper planarization layer 250b. The first electrode 260a corresponds to the connection electrode 248 and is connected to the connection electrode 248 through a contact hole in the upper planarization layer 250b. Alternatively, the connection electrode 248 may be omitted, and the first electrode 260a may be directly connected to the second source electrode 246a.

For example, the first electrode 260a is separately formed in each pixel region P. The first electrode 260a may be an anode and may include a transparent conductive oxide (TCO) layer, which is formed of a conductive material, e.g., a transparent conductive oxide material, having a relatively high work function, and a reflective layer.

For example, the transparent conductive oxide material may include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO), and the reflective layer may include at least one of silver (Ag), an alloy of Ag and one of palladium (Pd), Cu, In and Nd and aluminum-palladium-copper alloy (APC). For example, the first electrode 260a may have a double-layered structure of Ag/ITO or APC/ITO or a triple-layered structure of ITO/Ag/ITO or ITO/APC/ITO.

The bank 256 is formed on the upper planarization layer 250b at a boundary of the pixel region. The bank 256 covers an edge of the first electrode 260a and has a first opening to expose a center of the first electrode 260a. The bank 256 may include a light-absorbing particle, e.g., a black particle, to have a light-absorbing property.

An organic light emitting layer 260b covering the first electrode 260a and the bank 256 is disposed. The organic light emitting layer 260b contacts the first electrode 260a in the first opening of the bank 256.

A second electrode 260c is formed over the substrate 202 where the organic emitting layer 260b is formed. The second electrode 260c covers an entire surface of the display area. The second electrode 260c may be formed of at least one of ITO, IZO, Al, Ag, Cu, Pb, magnesium (Mg), Mo, Ti and their alloy and have a single-layered structure or a multi-layered structure. The second electrode 260c may have a thin profile (small thickness) to provide a light transmittance property (or a semi-transmittance property).

The first electrode 260a, the organic light emitting layer 260b and the second electrode 260c constitute an OLED D. The OLED D may emit the red, green and blue light in the red, green and blue pixel regions, respectively.

In the organic light emitting display device 200, the light from the organic light emitting layer 260b passes through the second electrode 260c to display an image. Namely, the organic light emitting display device 200 of the present disclosure is a top-emission type display device.

An encapsulation layer (or encapsulation film) 262 is formed on the second electrode 260c to prevent penetration of moisture into the OLED D. The encapsulation layer 262 may cover an entire substrate 202. The encapsulation layer 262 includes a first inorganic insulating layer 262a, an organic insulating layer 262b and a second inorganic insulating layer 262c sequentially stacked, but it is not limited thereto.

For example, each of the first inorganic insulating layer 262a and the second inorganic insulating layer 262c may be formed of an inorganic insulating material, e.g., silicon oxide or silicon nitride, and the organic insulating layer 262b may be formed of an organic insulating material, e.g., an acryl resin, an epoxy resin, a phenol resin, a polyamide resin or a PI resin.

A second buffer layer 264 is disposed on the encapsulation layer 262. The second buffer layer 264 may serve to block external moisture and/or oxygen. For example, the second buffer layer 264 may be formed of an inorganic insulating material, e.g., silicon oxide or silicon nitride, and may have a single-layered structure or a multi-layered structure.

A bridge pattern 266 is disposed on the second buffer layer 264. The bridge pattern 266 may correspond to a boundary of the pixel region P. For example, the bridge pattern 266 may be formed of one of ITO, IZO, Al, Ag, Cu, Pb, Mg, Mo, Ti and their alloy and have a single-layered structure or a multi-layered structure.

A touch interlayer insulating layer 270 is disposed on the bridge pattern 266 and over an entire substrate 202. For example, the touch interlayer insulating layer 270 may be formed of an organic insulating material, e.g., photo-acryl or BCB, and may have a single-layered structure or a multi-layered structure.

A touch electrode 272 is disposed on the touch interlayer insulating layer 270. The touch electrode 272 may correspond to a boundary of the pixel region P. The touch electrode 272 is connected to each other through the bridge pattern 266 on the touch interlayer insulating layer 270.

For example, the touch electrode 272 may be formed of one of ITO, IZO, Al, Ag, Cu, Pb, Mg, Mo, Ti and their alloy and have a single-layered structure or a multi-layered structure.

A third buffer layer 274 is disposed on the touch electrode 272. For example, the third buffer layer 274 may be formed of an inorganic insulating material, e.g., silicon oxide or silicon nitride, and may have a single-layered structure or a multi-layered structure.

A black matrix 282 is disposed on the third buffer layer 274. The black matrix 282 is positioned at a boundary of the pixel region P and has a second opening in correspondence to the OLED D. Namely, the second opening of the black matrix 282 corresponds to the first opening of the light-shielding bank 256.

A color filter layer 284 corresponding to the OLED D is disposed on the third buffer layer 274. Namely, the color filter layer 284 may correspond to the second opening of the black matrix 282. The color filter layer 284 may include a red color filter corresponding to the red pixel region, a green color filter corresponding to the green pixel region and a blue color filter corresponding to the blue pixel region.

A color conversion layer may be disposed between the OLED D and the color filter layer 284. The color conversion layer may include a red color conversion layer corresponding to the red pixel region, a green color conversion layer corresponding to the green pixel region and a blue color conversion layer corresponding to the blue pixel region. For example, the color conversion layer may include a quantum dot.

In FIG. 3, the bridge pattern 266, the touch electrode 272, the black matrix 282 and the color filter layer 284 are disposed over the OLED D. Alternatively, the bridge pattern 266, the touch electrode 272, the black matrix 282 and the color filter layer 284 may be omitted.

A protection layer 286 is disposed on the black matrix 282 and the color filter layer 284 and over an entire substrate 202. For example, the protection layer 286 may be formed of an organic insulating material, e.g., photo-acryl or BCB, and may have a single-layered structure or a multi-layered structure.

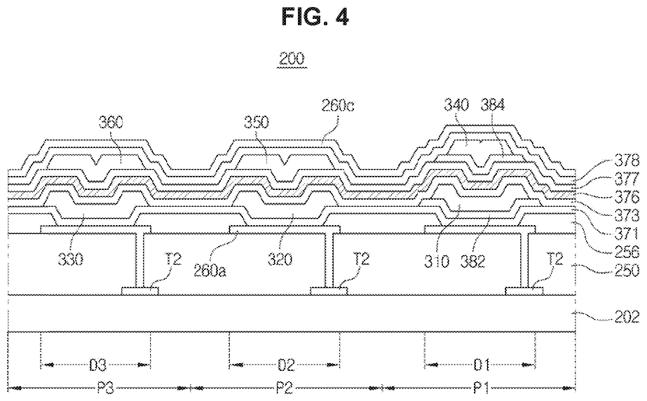

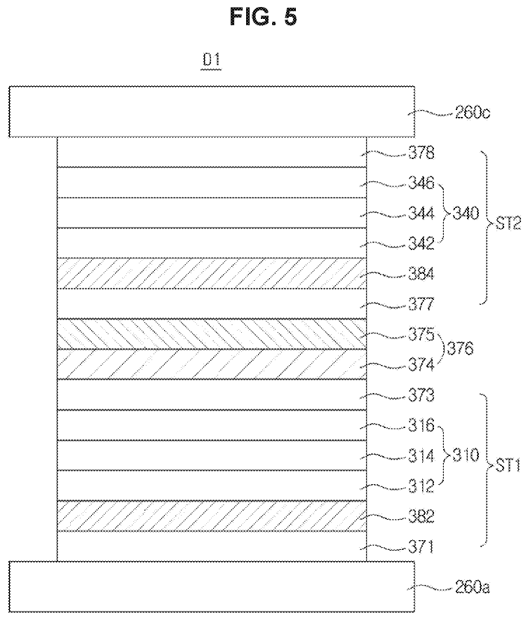

FIG. 4 is a schematic cross-sectional view of an organic light emitting display device according to the first implementation of the present disclosure, and FIG. 5 is a schematic cross-sectional view of an OLED for an organic light emitting display device according to the first implementation of the present disclosure.

Referring to FIGS. 4 and 5, first, second and third OLEDs D1, D2 and D3 are disposed over the substrate 202.

A first pixel region P1 as a blue pixel region, a second pixel region P2 as a green pixel region and a third pixel region P3 as a red pixel region are defined on the substrate 202, and the first to third OLEDs D1, D2 and D3 are disposed in the first to third pixel regions P1, P2 and P3, respectively. The first OLED D1 is a blue OLED emitting blue light, the second OLED D2 is a green OLED emitting green light, and the third OLED D3 is a red OLED emitting red light.

The second TFT T2 as a driving TFT is disposed on the substrate 202 and in each of the first to third pixel regions P1, P2 and P3, and each of the first to third OLEDs D1, D2 and D3 is connected to the second TFT T2 through a contact hole in the planarization layer 250.

Each of the first to third OLEDs D1, D2 and D3 has a double-stack structure. Namely, the first OLED D1 includes the first electrode 260a, a first emitting stack ST1, which includes a first blue emitting material layer (EML) 310, a first hole transporting layer (HTL) 371 and a first hole auxiliary layer 382, a second emitting stack ST2, which includes a second blue EML 340, a second HTL 377 and a second hole auxiliary layer 384, and the second electrode 260c. The second OLED D2 includes the first electrode 260a, a first emitting stack ST1, which includes a first green EML 320 and the first HTL 371, a second emitting stack ST2, which includes a second green EML 350 and a second HTL 377, and the second electrode 260c. The third OLED D3 includes the first electrode 260a, a first emitting stack ST1, which includes a first red EML 330 and the first HTL 371, a second emitting stack ST2, which includes a second red EML 360 and a second HTL 377, and the second electrode 260c. In each of the first to third OLEDs D1, D2 and D3, a charge generation layer (CGL) 376 is disposed between the first and second emitting stacks ST1 and ST2.

The first hole auxiliary layer 382 is positioned between the first HTL 371 and the first blue EML 310, and the second hole auxiliary layer 384 is positioned between the second HTL 377 and the second blue EML 340. Accordingly, the first blue EML 310 contacts the first hole auxiliary layer 382 and is spaced apart from the first HTL 371, and the second blue EML 340 contacts the second hole auxiliary layer 384 and is spaced apart from the second HTL 377. On the other hand, the first and second green EMLs 320 and 350 respectively contact the first and second HTLs 371 and 377, and the first and second red EMLs 330 and 360 respectively contact the first and second HTLs 371 and 377.

Each of the first blue EML 310 and the second blue EML 340 has a triple-layered structure. Namely, the first blue EML 310 includes a first blue emitting layer 312 on the first hole auxiliary layer 382, a second blue emitting layer 314 on the first blue emitting layer 312 and a third blue emitting layer 316 on the second blue emitting layer 314, and the second blue EML 340 includes a fourth blue emitting layer 342 on the second hole auxiliary layer 384, a fifth blue emitting layer 344 on the fourth blue emitting layer 342 and a sixth blue emitting layer 346 on the fifth blue emitting layer 344.

The first blue emitting layer 312 includes a first blue host and a first blue dopant, the second blue emitting layer 314 includes a second blue host and a second blue dopant, and the third blue emitting layer 316 includes a third blue host and a third blue dopant.

The fourth blue emitting layer 342 includes a fourth blue host and a fourth blue dopant, the fifth blue emitting layer 344 includes a fifth blue host and a fifth blue dopant, and the sixth blue emitting layer 346 includes a sixth blue host and a sixth blue dopant.

The first and third blue hosts may be the same material, and the second blue host may be different from the first and third blue hosts. The first to third dopants may be the same material. The fourth and sixth blue hosts may be the same material, and the fifth blue host may be different from the fourth and sixth blue hosts. The fourth to sixth dopants may be the same material.

Each of the first and second green EMLs 320 and 350 and the first and second red EMLs 330 and 360 may have a single-layered structure. Each of the first and second green EMLs 320 and 350 may include a green host and a green dopant, and each of the first and second red EMLs 330 and 360 may include a red host and a red dopant.

The first HTL 371 may include a first hole transporting material, and the second HTL 377 may include a second hole transporting material. The first and second hole transporting materials may be the same or different. The first hole auxiliary layer 382 may include a first hole auxiliary material, and the second hole auxiliary layer 384 may include a second hole auxiliary material. The first and second hole auxiliary materials may be the same or different.

In an aspect of the present disclosure, the first and second HTLs 371 and 377 may be formed of the same material, and the first and second hole auxiliary layers 382 and 384 may be formed of different materials.

A material of the first hole auxiliary layer 382 has a triplet energy being greater than the first blue dopant. For example, a difference between a triplet energy of the material of the first hole auxiliary layer 382 and a triplet energy of the first blue dopant may be 0.2 eV or more, preferably in a range of 0.2 to 0.3 eV. In addition, the first blue host has a triplet energy being smaller than the first blue dopant and being greater than the second blue host.

A material of the second hole auxiliary layer 384 has a triplet energy being greater than the fourth blue dopant. For example, a difference between a triplet energy of the material of the second hole auxiliary layer 384 and a triplet energy of the fourth blue dopant may be 0.2 eV or more, preferably in a range of 0.2 to 0.3 eV. In addition, the fourth blue host has a triplet energy being smaller than the fourth blue dopant and being greater than the fifth blue host.

As a result, an exciton is confined in the second blue host having a relatively low triplet energy, and a recombination zone is presented in the second blue emitting layer 314 at a center of the first blue EML 310. In addition, an exciton is confined in the fifth blue host having a relatively low triplet energy, and a recombination zone is presented in the fifth blue emitting layer 344 at a center of the second blue EML 340. Accordingly, the emitting efficiency and the lifespan of the first OLED D1 are improved.

The first hole auxiliary layer 382 has a hole mobility being smaller than that of the first HTL 371, and the second hole auxiliary layer 384 has a hole mobility being smaller than that of the second HTL 377.

In addition, the hole mobility of the first hole auxiliary layer 382 is smaller than that of the second hole auxiliary layer 384. Namely, the hole mobility of the first hole auxiliary layer 382 in the first emitting stack ST1, which is positioned to be closer to the first electrode 260a as an anode, is smaller than that of the second hole auxiliary layer 384 in the second emitting stack ST2, which is positioned to be closer to the second electrode 260c as a cathode.

The hole mobility of each of the first and second HTLs 371 and 377 may be 10 times or more of that of the second hole auxiliary layer 384, and the hole mobility of the second hole auxiliary layer 384 may be 10 times or more of that of the first hole auxiliary layer 382.

For example, the hole mobility of each of the first and second HTLs 371 and 377 may be in a range 1×10⁻⁵ cm²/Vs to 1×10⁻³ cm²/Vs, the hole mobility of the first hole auxiliary layer 382 may be in a range 1×10⁻⁷ cm²/Vs to 1×10⁻⁶ cm²/Vs, and the hole mobility of the second hole auxiliary layer 384 may be in a range 1×10⁻⁶ cm²/Vs to 1×10⁻⁵ cm²/Vs. However, it is not limited thereto. Namely, in the organic light emitting display device 200 of the present disclosure, a relationship between small and large of the hole mobility of the first HTL 371, the hole mobility of the second HTL 377, the hole mobility of the first hole auxiliary layer 382 and the hole mobility of the second hole auxiliary layer 384 is one of important facts, while ranges of the hole mobility of the first HTL 371, the hole mobility of the second HTL 377, the hole mobility of the first hole auxiliary layer 382 and the hole mobility of the second hole auxiliary layer 384 may not be an important fact.

The hole mobility was measured using a hole-only device (HOD) and J-V fitting based on the space charge limited current (SCLC) relationship.

Each of the first and second OLEDs D1 and D2 can be configured with an appropriate (or a desired) low-grayscale capacitance so that a low-grayscale response time (e.g., response speed) of the organic light emitting display device 200 can be improved and/or a driving voltage of the organic light emitting display device 200 can be reduced. For example, each of the first and second OLEDs D1 and D2 can be configured with an appropriate threshold voltage so that a low-grayscale response time of the organic light emitting display device 200 can be improved and/or a driving voltage of the organic light emitting display device 200 can be reduced.

Otherwise, if the first and second HTLs 371 and 377 and the first and second hole auxiliary layers 382 and 384 do not satisfy the above conditions, then the low-grayscale capacitance of the first and second OLEDs D1 and D2 is degraded so that the low-grayscale response time may be increased and/or the driving voltage may be increased. As such, in the organic light emitting display device 200 according to implementations of the present disclosure, the first and second HTLs 371 and 377, the first and second hole auxiliary layers 382 and 384 and the first blue emitting layer 312, the second blue emitting layer 314, the fourth blue emitting layer 342 and the fifth blue emitting layer 344 satisfy the above conditions. This can have a technical effect of mitigating and reducing malfunction of the organic light emitting display device 200 and/or reducing the driving voltage of the organic light emitting display device 200 along with improving emitting efficiency and lifespan.

The first emitting stack ST1 of each of the first to third OLEDs D1, D2 and D3 may further include a first electron transporting layer (ETL) 373 on each of the first blue EML 310, the first green EML 320, and the first red EML 330.

In addition, the first emitting stack ST1 of each of the first to third OLEDs D1, D2 and D3 may further include a hole injection layer (HIL) between the first electrode 260a and the first HTL 371.

The second emitting stack ST2 of each of the first to third OLEDs D1, D2 and D3 may further include a second ETL 378 on each of the second blue EML 340, the second green EML 350, and the second red EML 360.

In addition, the second emitting stack ST2 of each of the first to third OLEDs D1, D2 and D3 may further include an electron injection layer between the second ETL 378 and the second electrode 260c.

The CGL 376 may include an n-type CGL 374 and a p-type CGL 375 on the n-type CGL 374. An electron is transferred and/or injected into the first emitting stack ST1 by the n-type CGL 374, and a hole is transferred and/or injected into the second emitting stack ST2 by the p-type CGL 375.

As mentioned above, in the organic light emitting display device 200 of the present disclosure, the OLED D has a double-stack structure, and each of the first and second blue EMLs 310 and 340 has a triple-layered structure. The first and second HTLs 371 and 377, the first and second hole auxiliary layers 382 and 384, the first blue host and the first blue dopant of the first blue emitting layer 312, the second blue host of the second blue emitting layer 314, the fourth blue host and the fourth blue dopant of the fourth blue emitting layer 342, the fifth blue host of the fifth blue emitting layer 344 satisfy the above condition (or relation) so that the emitting efficiency and the lifespan of the first OLED D1 in the first pixel region P1 as a blue pixel region can be improved.

In addition, the first and second HTLs 371 and 377 and the first and second hole auxiliary layers 382 and 384 satisfy the above conditions, the first OLED D1 has an appropriate low-grayscale capacitance. Accordingly, the low-grayscale response time of the organic light emitting display device 200 can be improved, and/or the driving voltage of the organic light emitting display device 200 can be reduced.

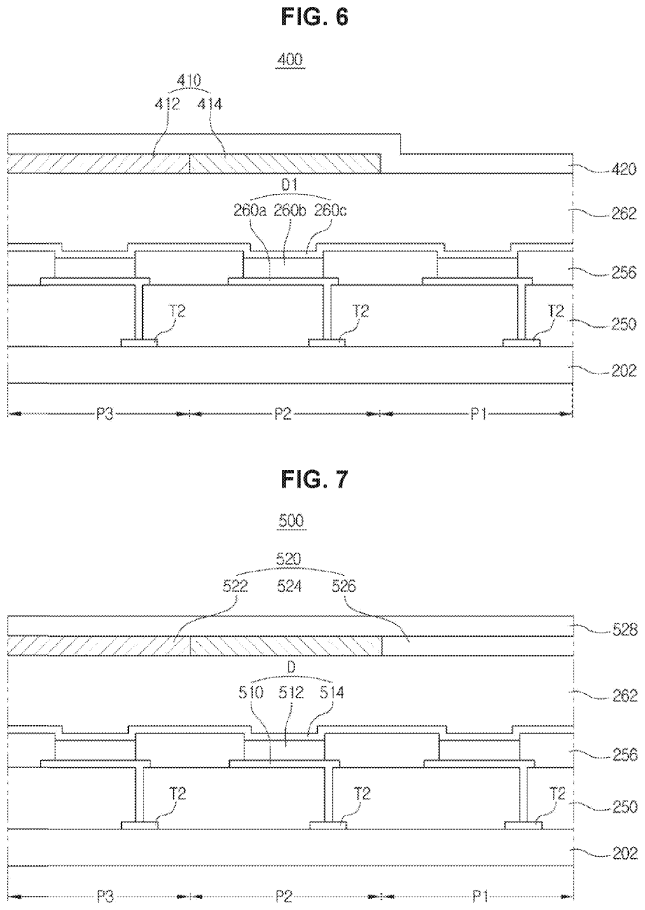

FIG. 6 is a schematic cross-sectional view of an organic light emitting display device according to a second implementation of the present disclosure.

As shown in FIG. 6, the organic light emitting display device 400 includes a substrate 202 including first to third pixel regions P1, P2 and P3, an OLED D1 disposed over the substrate 202 and in the first to third pixel regions P1, P2 and P3 and a color conversion layer 410 disposed over the OLED D1 and corresponding to the second and third pixel regions P2 and P3.

The first to third pixel regions P1, P2 and P3 may be blue, green and red pixel regions, respectively.

A second TFT T2, which corresponds to the first to third pixel regions P1, P2 and P3, and a planarization layer 250, which covers the second TFT T2, are disposed between the substrate 202 and the OLED D1.

The OLED D1 is disposed in the first to third pixel regions P1, P2 and P3 and provide a blue emission. Namely, the OLED D1 is a blue OLED. The OLED D1 includes a first electrode 260a as an anode, an organic light emitting layer 260b and a second electrode 260c as a cathode. The OLED D1 is disposed on the planarization layer 250, and the first electrode 260a is connected to the second TFT T2 through a contact hole in the planarization layer 250.

Referring to FIG. 5, the organic light emitting layer 260b includes the first emitting stack ST1, which includes the first blue EML 310, the first HTL 371 and the first hole auxiliary layer 382, and the second emitting stack ST2, which includes the second blue EML 340, the second HTL 377 and the second hole auxiliary layer 384.

A bank 256, which is disposed at a boundary of the first to third pixel regions P1, P2 and P3 and includes an opening in correspondence to the OLED D1, is disposed on the planarization layer 250.

An encapsulation layer 262 is disposed on the OLED D1 and over an entire surface of the substrate 202. The encapsulation layer 262 may include a first inorganic insulating layer, an organic insulating layer on the first inorganic insulating layer and a second inorganic insulating layer on the organic insulating layer.

The color conversion layer 410 is disposed on or over the encapsulation layer 262. The color conversion layer 410 may include a green color conversion layer 414 corresponding to the second pixel region P2 and a red color conversion layer 412 corresponding to the third pixel region P3. The color conversion layer 410 is not presented in the first pixel region P1 as a blue pixel region. For example, the color conversion layer 410 may include a quantum dot.

A protection layer 420 is disposed over an entire surface of the substrate 202 to cover the color conversion layer 410.

The organic light emitting display device 400 may further include a color filter layer between the color conversion layer 410 and the protection layer 420. The color filter layer may include a green color filter layer corresponding to the second pixel region P2 and a red color filter layer corresponding to the third pixel region P3. The color filter layer may further include a blue color filter layer corresponding to the first pixel region P1.

The OLED D1 emits blue light. The blue light from the OLED D1 can be converted into green light by the green color conversion layer in the second pixel region P2 and red light by the red color conversion layer in the third pixel region P3.

In addition, in the OLED D1, the first and second HTLs 371 and 377, the first and second hole auxiliary layers 382 and 384, the first blue host and the first blue dopant of the first blue emitting layer 312, the second blue host of the second blue emitting layer 314, the fourth blue host and the fourth blue dopant of the fourth blue emitting layer 342, the fifth blue host of the fifth blue emitting layer 344 satisfy the above condition (or relation) so that the emitting efficiency and the lifespan of the OLED D1 can be improved.

Moreover, the first and second HTLs 371 and 377 and the first and second hole auxiliary layers 382 and 384 satisfy the above conditions, the OLED D1 has an appropriate low-grayscale capacitance. Accordingly, the low-grayscale response time of the organic light emitting display device 400 can be improved, and/or the driving voltage of the organic light emitting display device 400 can be reduced.

FIG. 7 is a schematic cross-sectional view of an organic light emitting display device according to a third implementation of the present disclosure.

As shown in FIG. 7, the organic light emitting display device 500 includes a substrate 202 including first to third pixel regions P1, P2 and P3, an OLED D disposed over the substrate 202 and in the first to third pixel regions P1, P2 and P3 and a color filter layer 520 disposed over the OLED D and corresponding to the first to third pixel regions P1, P2 and P3.

The first to third pixel regions P1, P2 and P3 may be blue, green and red pixel regions, respectively.

A second TFT T2, which corresponds to the first to third pixel regions P1, P2 and P3, and a planarization layer 250, which covers the second TFT T2, are disposed between the substrate 202 and the OLED D.

The OLED D is disposed in the first to third pixel regions P1, P2 and P3 and provides a white emission. Namely, the OLED D is a white OLED. The OLED D includes a first electrode 510 as an anode, an organic light emitting layer 512 and a second electrode 514 as a cathode. The OLED D is disposed on the planarization layer 250, and the first electrode 510 is connected to the second TFT T2 through a contact hole in the planarization layer 250.

A bank 256, which is disposed at a boundary of the first to third pixel regions P1, P2 and P3 and includes an opening in correspondence to the OLED D, is disposed on the planarization layer 250.

An encapsulation layer 262 is disposed on the OLED D and over an entire surface of the substrate 202. The encapsulation layer 262 may include a first inorganic insulating layer, an organic insulating layer on the first inorganic insulating layer and a second inorganic insulating layer on the organic insulating layer.

The color filter layer 520 is disposed on or over the encapsulation layer 262. The color filter layer 520 may include a blue color filter layer 526 corresponding to the first pixel region P1, a green color filter layer 524 corresponding to the second pixel region P2 and a red color filter layer 522 corresponding to the third pixel region P3. The blue color filter layer 526 may include at least one of a blue pigment and a blue dye, the green color filter layer 524 may include at least one of a green pigment and a green dye, and the red color filter layer 522 may include at least one of a red pigment and a red dye.

A protection layer 528 is disposed over an entire surface of the substrate 202 to cover the color filter layer 520.

The organic light emitting display device 500 may further include a color conversion layer between the color filter layer 520 and the OLED D.

The OLED D emits white light. The white light can be filtered by the color filter layer so that a full-color image can be displayed.

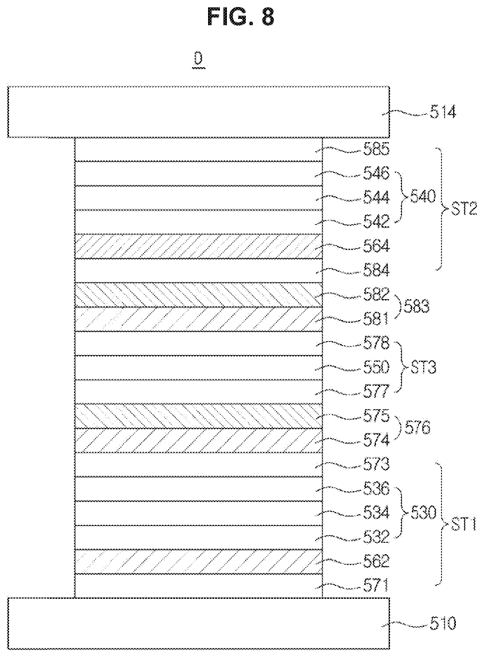

FIG. 8 is a schematic cross-sectional view of an OLED of an organic light emitting display device according to the third implementation of the present disclosure.

As shown in FIG. 8, the OLED D includes a first electrode 510, a second electrode 514 and an organic light emitting layer between the first and second electrodes 510 and 514. The organic light emitting layer includes a first emitting stack ST1, which includes a first EML 530, a first HTL 571 and a first hole auxiliary layer 562, a second emitting stack ST2, which includes a second EML 540, a second HTL 584 and a second hole auxiliary layer 564, a third emitting stack ST3, which includes a third EML 550, a first CGL 576 and a second CGL 583.

The first emitting stack ST1 is positioned to be closer to the first electrode 510 as an anode, and the second emitting stack ST2 is positioned to be closer to the second electrode 514 as a cathode. The third emitting stack ST3 is positioned between the first and second emitting stacks ST1 and ST2.

Each of the first and second EMLs 530 and 540 emits blue light, and the third EML 550 emits red-green light or yellow-green light.

In the first emitting stack ST1, the first hole auxiliary layer 562 is positioned between the first HTL 571 and the first EML 530. The first emitting stack ST1 may further include a first ETL 573 on the first EML 530. In addition, the first emitting stack ST1 may further include an HIL under the first HTL 571.

In the second emitting stack ST2, the second hole auxiliary layer 564 is positioned between the second HTL 584 and the second EML 540. The second emitting stack ST2 may further include a second ETL 585 on the second EML 540. In addition, the second emitting stack ST2 may further include an EIL on the second ETL 585.

In the third emitting stack ST3, the third EML 550 may include a red emitting layer and a green emitting layer on the red emitting layer. Alternatively, the third EML 550 may have a single-layered structure including a yellow-green emitting layer. The third emitting stack ST3 may further include at least one of a third HTL 577 under the third EML 550 and a third ETL 578 on the third EML 550.

The first CGL 576 is disposed between the first and third emitting stacks ST1 and ST3, and the second CGL 583 is disposed between the second and third emitting stacks ST2 and ST3.

The first CGL 576 may include a first n-type CGL 574 and a first p-type CGL 575 on the first n-type CGL 574, and the second CGL 583 may include a second n-type CGL 581 and a second p-type CGL 582 on the second n-type CGL 581.

Each of the first and second EMLs 530 and 540 is a blue EML and has a triple-layered structure. Namely, the first EML 530 includes a first blue emitting layer 532 on the first hole auxiliary layer 562, a second blue emitting layer 534 on the first blue emitting layer 532 and a third blue emitting layer 536 on the second blue emitting layer 534, and the second EML 540 includes a fourth blue emitting layer 542 on the second hole auxiliary layer 564, a fifth blue emitting layer 544 on the fourth blue emitting layer 542 and a sixth blue emitting layer 546 on the fifth blue emitting layer 544.

The first blue emitting layer 532 includes a first blue host and a first blue dopant, the second blue emitting layer 534 includes a second blue host and a second blue dopant, and the third blue emitting layer 536 includes a third blue host and a third blue dopant.

The fourth blue emitting layer 542 includes a fourth blue host and a fourth blue dopant, the fifth blue emitting layer 544 includes a fifth blue host and a fifth blue dopant, and the sixth blue emitting layer 546 includes a sixth blue host and a sixth blue dopant.

The first and third blue hosts may be the same material, and the second blue host may be different from the first and third blue hosts. The first to third dopants may be the same material. The fourth and sixth blue hosts may be the same material, and the fifth blue host may be different from the fourth and sixth blue hosts. The fourth to sixth dopants may be the same material.

The third EML 550 may be a yellow-green EML and include a yellow-green host and a yellow-green dopant. Alternatively, the third EML 550 may have a double-layered structure including a red emitting layer and a green emitting layer on the red emitting layer or a triple-layered structure including a red emitting layer, a yellow-green emitting layer on the red emitting layer and a green emitting layer on the yellow-green emitting layer. The red emitting layer may include a red host and a red dopant, the green emitting layer may include a green host and a green dopant.

The first HTL 571 may include a first hole transporting material, and the second HTL 584 may include a second hole transporting material. The first and second hole transporting materials may be the same or different. The first hole auxiliary layer 562 may include a first hole auxiliary material, and the second hole auxiliary layer 564 may include a second hole auxiliary material. The first and second hole auxiliary materials may be the same or different.

In an aspect of the present disclosure, the first and second HTLs 571 and 584 may be formed of the same material, and the first and second hole auxiliary layers 562 and 564 may be formed of different materials.

A material of the first hole auxiliary layer 562 has a triplet energy being greater than the first blue dopant. For example, a difference between a triplet energy of the material of the first hole auxiliary layer 562 and a triplet energy of the first blue dopant may be 0.2 eV or more, preferably in a range of 0.2 to 0.3 eV. In addition, the first blue host has a triplet energy being smaller than the first blue dopant and being greater than the second blue host.

A material of the second hole auxiliary layer 564 has a triplet energy being greater than the fourth blue dopant. For example, a difference between a triplet energy of the material of the second hole auxiliary layer 564 and a triplet energy of the fourth blue dopant may be 0.2 eV or more, preferably in a range of 0.2 to 0.3 eV. In addition, the fourth blue host has a triplet energy being smaller than the fourth blue dopant and being greater than the fifth blue host.

As a result, an exciton is confined in the second blue host having a relatively low triplet energy, and a recombination zone is presented in the second blue emitting layer 534 at a center of the first blue EML 530. In addition, an exciton is confined in the fifth blue host having a relatively low triplet energy, and a recombination zone is presented in the fifth blue emitting layer 544 at a center of the second blue EML 540. Accordingly, the emitting efficiency and the lifespan of the OLED D are improved.

The first hole auxiliary layer 562 has a hole mobility being smaller than the first HTL 571, and the second hole auxiliary layer 564 has a hole mobility being smaller than the second HTL 584.

In addition, the hole mobility of the first hole auxiliary layer 562 is smaller than that of the second hole auxiliary layer 564. Namely, the hole mobility of the first hole auxiliary layer 562 in the first emitting stack ST1, which is positioned to be closer to the first electrode 510 as an anode, is smaller than that of the second hole auxiliary layer 564 in the second emitting stack ST2, which is positioned to be closer to the second electrode 514 as a cathode.

The hole mobility of each of the first and second HTLs 571 and 584 may be 10 times or more of that of the second hole auxiliary layer 564, and the hole mobility of the second hole auxiliary layer 564 may be 10 times or more of that of the first hole auxiliary layer 562.

For example, the hole mobility of each of the first and second HTLs 571 and 584 may be in a range 1×10⁻⁵ cm²/Vs to 1×10⁻³ cm²/Vs, the hole mobility of the first hole auxiliary layer 562 may be in a range 1×10⁻⁷ cm²/Vs to 1×10⁻⁶ cm²/Vs, and the hole mobility of the second hole auxiliary layer 564 may be in a range 1×10⁻⁶ cm³/Vs to 1×10⁻⁵ cm²/Vs. However, it is not limited thereto. Namely, in the organic light emitting display device 500 of the present disclosure, a relationship between small and large of the hole mobility of the first HTL 571, the hole mobility of the second HTL 584, the hole mobility of the first hole auxiliary layer 562 and the hole mobility of the second hole auxiliary layer 564 is one of important facts, while ranges of the hole mobility of the first HTL 571, the hole mobility of the second HTL 584, the hole mobility of the first hole auxiliary layer 562 and the hole mobility of the second hole auxiliary layer 564 may not be an important fact.

The hole mobility was measured using a hole-only device (HOD) and J-V fitting based on the space charge limited current (SCLC) relationship.

The OLED D has an appropriate low-grayscale capacitance, which can improve a low-grayscale response time of the organic light emitting display device 500 and/or reduce a driving voltage of the organic light emitting display device 500. As such, the OLED D can be configured with an appropriate threshold voltage, which can improve a low-grayscale response time of the organic light emitting display device 500 and/or reduce a driving voltage of the organic light emitting display device 500.

Otherwise, if the first and second HTLs 571 and 584 and the first and second hole auxiliary layers 562 and 564 do not satisfy the above conditions, then the low-grayscale capacitance of the OLED D is degraded so that the low-grayscale response time may be increased and/or the driving voltage may be increased. As such, in the organic light emitting display device 500 according to implementations of the present disclosure, the first and second HTLs 571 and 584, the first and second hole auxiliary layers 562 and 564 and the first blue emitting layer 532, the second blue emitting layer 534, the fourth blue emitting layer 542 and the fifth blue emitting layer 544 satisfy the above conditions. This can have a technical effect of mitigating or preventing malfunction of the organic light emitting display device 500 and/or reducing the driving voltage of the organic light emitting display device 500, along with improving emitting efficiency and lifespan.

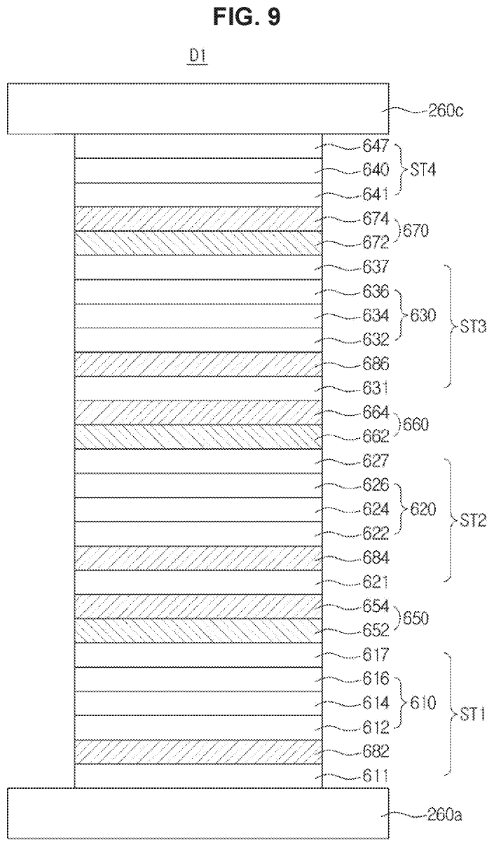

FIG. 9 is a schematic cross-sectional view of an OLED of an organic light emitting display device according to the first and second implementations of the present disclosure.

As shown in FIG. 9, the OLED D1 includes a first electrode 260a, a second electrode 260c and an organic light emitting layer between the first and second electrodes 260a and 260c. The organic light emitting layer includes a first emitting stack ST1, which includes a first EML 610, a first HTL 611 and a first hole auxiliary layer 682, a second emitting stack ST2, which includes a second EML 620, a second HTL 621 and a second hole auxiliary layer 684, a third emitting stack ST3, which includes a third EML 630, a third HTL 631 and a third hole auxiliary layer 686, a fourth emitting stack ST4 including a fourth EML 640, a first CGL 650, a second CGL 660 and a third CGL 670.

The first emitting stack ST1 is positioned to be closer to the first electrode 260a as an anode than the second to fourth emitting stacks ST2, ST3 and ST4, and the third emitting stack ST3 is positioned to be closer to the second electrode 260c as a cathode than the first and second emitting stacks ST1 and ST2. The second emitting stack ST2 is positioned to be closer to the second electrode 260c than the first emitting stack ST1 and to be closer to the first electrode 260a than the third emitting stack ST3.

Each of the first to third EMLs 610, 620 and 630 emits blue light, and the fourth EML 640 emits green light.

In the first emitting stack ST1, the first hole auxiliary layer 682 is positioned between the first HTL 611 and the first EML 610. The first emitting stack ST1 may further include a first ETL 617 on the first EML 610. In addition, the first emitting stack ST1 may further include an HIL under the first HTL 611.

In the second emitting stack ST2, the second hole auxiliary layer 684 is positioned between the second HTL 621 and the second EML 620. The second emitting stack ST2 may further include a second ETL 627 on the second EML 620.

In the third emitting stack ST3, the third hole auxiliary layer 686 is positioned between the third HTL 631 and the third EML 630. The third emitting stack ST3 may further include a third ETL 637 on the third EML 630.

The fourth emitting stack ST4 may further include at least one of a fourth HTL 641 under the fourth EML 640 and a fourth ETL 647 on the fourth EML 640. In addition, the fourth emitting stack ST4 may further include an EIL on the fourth ETL 647.

The first CGL 650 is positioned between the first and second emitting stacks ST1 and ST2, the second CGL 660 is positioned between the second and third emitting stacks ST2 and ST3, and the third CGL 670 is positioned between the third and fourth emitting stacks ST3 and ST4.

The first CGL 650 may include a first n-type CGL 652 and a first p-type CGL 654 on the first n-type CGL 652. The second CGL 660 may include a second n-type CGL 662 and a second p-type CGL 664 on the second n-type CGL 662. The third CGL 670 may include a third n-type CGL 672 and a third p-type CGL 674 on the third n-type CGL 672.

Each of the first to third EMLs 610, 620 and 630 is a blue EML and has a triple-layered structure. Namely, the first EML 610 includes a first blue emitting layer 612 on the first hole auxiliary layer 682, a second blue emitting layer 614 on the first blue emitting layer 612 and a third blue emitting layer 616 on the second blue emitting layer 614. The second EML 620 includes a fourth blue emitting layer 622 on the second hole auxiliary layer 684, a fifth blue emitting layer 624 on the fourth blue emitting layer 622 and a sixth blue emitting layer 626 on the fifth blue emitting layer 624.

The third EML 630 includes a seventh blue emitting layer 632 on the third hole auxiliary layer 686, an eighth blue emitting layer 634 on the seventh blue emitting layer 632 and a ninth blue emitting layer 636 on the eighth blue emitting layer 634.

The first blue emitting layer 612 includes a first blue host and a first blue dopant, the second blue emitting layer 614 includes a second blue host and a second blue dopant, and the third blue emitting layer 616 includes a third blue host and a third blue dopant.

The fourth blue emitting layer 622 includes a fourth blue host and a fourth blue dopant, the fifth blue emitting layer 624 includes a fifth blue host and a fifth blue dopant, and the sixth blue emitting layer 626 includes a sixth blue host and a sixth blue dopant.

The seventh blue emitting layer 632 includes a seventh blue host and a seventh blue dopant, the eighth blue emitting layer 634 includes an eighth blue host and an eighth blue dopant, and the ninth blue emitting layer 636 includes a ninth blue host and a ninth blue dopant.

The first and third blue hosts may be the same material, and the second blue host may be different from the first and third blue hosts. The first to third dopants may be the same material. The fourth and sixth blue hosts may be the same material, and the fifth blue host may be different from the fourth and sixth blue hosts. The fourth to sixth dopants may be the same material. The seventh and ninth blue hosts may be the same material, and the eighth blue host may be different from the seventh and ninth blue hosts. The seventh to ninth dopants may be the same material.

The fourth EML 640 is a green EML including a green host and a green dopant.

In an aspect of the present disclosure, at least one of the first to ninth blue host, the first to ninth blue dopant, the green host and the green dopant may be a deuterated compound (e.g., a compound substituted with deuterium). For example, at least one of the first to ninth blue host and the first to ninth blue dopant may be a deuterated compound, and each of the green host, the green dopant and the rest of the first to ninth blue host and the first to ninth blue dopant may be a non-deuterated compound. Alternatively, at least one of the green host and the green dopant may be a deuterated compound, and each of the first to ninth blue host, the first to ninth blue dopant and the rest of the green host and the green dopant may be a non-deuterated compound.

The first HTL 611 may include a first hole transporting material, the second HTL 621 may include a second hole transporting material, and the third HTL 631 may include a third hole transporting material. The first to third hole transporting materials may be the same or different. The first hole auxiliary layer 682 may include a first hole auxiliary material, the second hole auxiliary layer 684 may include a second hole auxiliary material, and the third hole auxiliary layer 686 may include a third hole auxiliary material. The first to third hole auxiliary materials may be the same or different.

In an aspect of the present disclosure, the first to third HTLs 611, 621 and 631 may be formed of the same material, and the first to third hole auxiliary layers 682, 684 and 686 may be formed of different materials.

A material of the first hole auxiliary layer 682 has a triplet energy being greater than the first blue dopant. For example, a difference between a triplet energy of the material of the first hole auxiliary layer 682 and a triplet energy of the first blue dopant may be 0.2 eV or more, preferably in a range of 0.2 to 0.3 eV. In addition, the first blue host has a triplet energy being smaller than the first blue dopant and being greater than the second blue host.

A material of the second hole auxiliary layer 684 has a triplet energy being greater than the fourth blue dopant. For example, a difference between a triplet energy of the material of the second hole auxiliary layer 684 and a triplet energy of the fourth blue dopant may be 0.2 eV or more, preferably in a range of 0.2 to 0.3 eV. In addition, the fourth blue host has a triplet energy being smaller than the fourth blue dopant and being greater than the fifth blue host.

A material of the third hole auxiliary layer 686 has a triplet energy being greater than the seventh blue dopant. For example, a difference between a triplet energy of the material of the third hole auxiliary layer 686 and a triplet energy of the seventh blue dopant may be 0.2 eV or more, preferably in a range of 0.2 to 0.3 eV. In addition, the seventh blue host has a triplet energy being smaller than the seventh blue dopant and being greater than the eighth blue host.

As a result, an exciton is confined in the second blue host having a relatively low triplet energy, and a recombination zone is presented in the second blue emitting layer 614 at a center of the first blue EML 610. In addition, an exciton is confined in the fifth blue host having a relatively low triplet energy, and a recombination zone is presented in the fifth blue emitting layer 624 at a center of the second blue EML 620. Moreover, an exciton is confined in the eighth blue host having a relatively low triplet energy, and a recombination zone is presented in the eighth blue emitting layer 634 at a center of the third blue EML 630. Accordingly, the emitting efficiency and the lifespan of the OLED D1 are improved.

The first hole auxiliary layer 682 has a hole mobility being smaller than the first HTL 611, the second hole auxiliary layer 684 has a hole mobility being smaller than the second HTL 621, and the third hole auxiliary layer 686 has a hole mobility being smaller than the third HTL 631.

The hole mobility of the second hole auxiliary layer 684 is greater than that of the first hole auxiliary layer 682 and smaller than that of the third hole auxiliary layer 686. Namely, the hole mobility of the first hole auxiliary layer 682 in the first emitting stack ST1, which is closer to the first electrode 260a as an anode than the second and third emitting stacks ST2 and ST3, is smaller than the hole mobility of each of the second and third hole auxiliary layers 684 and 686 in the second and third emitting stacks ST2 and ST3, each of which is closer to the second electrode 260c than the first emitting stack ST1.

In addition, the hole mobility of the third hole auxiliary layer 686 in the third emitting stack ST3, which is closer to the second electrode 260c as a cathode than the first and second emitting stacks ST1 and ST2, is greater than the hole mobility of each of the first and second hole auxiliary layers 682 and 684 in the first and second emitting stacks ST1 and ST2, each of which is closer to the first electrode 260a as an anode than the third emitting stack ST3.

The hole mobility of each of the first to third HTLs 611, 621 and 631 may be 10 times or more of that of the third hole auxiliary layer 686, and the hole mobility of the third hole auxiliary layer 686 may be 10 times or more of that of the first hole auxiliary layer 682.

The OLED D1 has an appropriate low-grayscale capacitance, which can improve a low-grayscale response time of the organic light emitting display device and/or reduce a driving voltage of the organic light emitting display device. As such, the OLED D1 can be configured with an appropriate threshold voltage which can improve a low-grayscale response time of the organic light emitting display device and/or reduce a driving voltage of the organic light emitting display device.

The OLED D1 in FIG. 9 emits blue light. Referring to FIG. 4, the OLED D1 in FIG. 9 may be disposed only in the first pixel region P1 as a blue pixel region. Referring to FIG. 6, the OLED D1 in FIG. 9 may be disposed in the first pixel region P1 as a blue pixel region, the second pixel region P2 as a green pixel region and the third pixel region P3 as a red pixel region, and a full-color image can be displayed using the color conversion layer 410.

### Evaluation of OLED's Properties

The threshold voltage (Vth) and the emitting efficiency of the OLED (Ex) in the organic light emitting display device according to the first implementation of the present disclosure, the OLED (Ref1) without first and second hole auxiliary layers, and the OLED (Ref2) without second hole auxiliary layer were measured and example results are listed in Table 1. The properties of the OLED were measured by driving at 1 KHz and performing a voltage sweep using the Probe station B1500A equipment.

TABLE 1

| | Vth | Efficiency |
|---|---|---|
| Ref1 | — | 100% |
| Ref2 | +0.09 V | 102% |
| Ex | +0.19 V | 102% |

As shown in Table 1, the OLED includes a first hole auxiliary layer between the first HTL and the first blue EML and a second hole auxiliary layer between the second HTL and the second blue EML so that the low-grayscale capacitance (threshold voltage) is increased and the emitting efficiency is improved. Accordingly, the emitting efficiency of the organic light emitting display device is improved and the low-grayscale response time is improved.

It will be apparent to those skilled in the art that various modifications and variations can be made in the implementations of the present disclosure without departing from the technical idea or scope of the present disclosure. Thus, it is intended that the modifications and variations cover this disclosure provided they come within the scope of the appended claims and their equivalents.

What is claimed is:

1. An organic light emitting diode, comprising:
a first electrode;
a second electrode facing the first electrode;
a first emitting stack positioned between the first electrode and the second electrode and including (i) a first hole transporting layer, (ii) a first hole auxiliary layer on the first hole transporting layer, and (iii) a first emitting material layer on the first hole auxiliary layer;
a second emitting stack positioned between the first emitting stack and the second electrode and including (i) a second hole transporting layer, (ii) a second hole auxiliary layer on the second hole transporting layer, and (iii) a second emitting material layer on the second hole auxiliary layer; and
a first charge generation layer between the first emitting stack and the second emitting stack,
wherein the first emitting material layer includes (i) a first blue emitting layer on the first hole auxiliary layer, (ii) a second blue emitting layer on the first blue emitting layer, and (iii) a third blue emitting layer on the second blue emitting layer,
wherein the second emitting material layer includes (i) a fourth blue emitting layer on the second hole auxiliary layer, (ii) a fifth blue emitting layer on the fourth blue emitting layer, and (iii) a sixth blue emitting layer on the fifth blue emitting layer,
wherein a hole mobility of the first hole transporting layer is greater than a hole mobility of the first hole auxiliary layer, and a hole mobility of the second hole transporting layer is greater than a hole mobility of the second hole auxiliary layer, and
wherein the hole mobility of the second hole auxiliary layer is greater than the hole mobility of the first hole auxiliary layer.

2. The organic light emitting diode according to claim 1, wherein the hole mobility of each of the first hole transporting layer and the second hole transporting layer is in a range 1×10⁻⁵ cm²/Vs to 1×10⁻³ cm²/Vs,
wherein the hole mobility of the first hole auxiliary layer is in a range 1×10⁻⁷ cm³/Vs to 1×10⁻⁶ cm²/Vs, and
wherein the hole mobility of the second hole auxiliary layer is in a range 1×10⁻⁶ cm²/Vs to 1×10⁻⁵ cm²/Vs.

3. The organic light emitting diode according to claim 1, wherein the first blue emitting layer includes a first blue host and a first blue dopant,
wherein the second blue emitting layer includes a second blue host and a second blue dopant,
wherein the third blue emitting layer includes a third blue host and a third blue dopant,
wherein the fourth blue emitting layer includes a fourth blue host and a fourth blue dopant,
wherein the fifth blue emitting layer includes a fifth blue host and a fifth blue dopant, and
wherein the sixth blue emitting layer includes a sixth blue host and a sixth blue dopant.

4. The organic light emitting diode according to claim 3, wherein a triplet energy of the first hole auxiliary layer is greater than a triplet energy of the first blue dopant.

5. The organic light emitting diode according to claim 4, wherein a difference between the triplet energy of the first hole auxiliary layer and the triplet energy of the first blue dopant is 0.2 eV or more.

6. The organic light emitting diode according to claim 4, wherein a triplet energy of the first blue host is smaller than the triplet energy of the first blue dopant and greater than a triplet energy of the second blue host.

7. The organic light emitting diode according to claim 3, wherein a triplet energy of the second hole auxiliary layer is greater than a triplet energy of the fourth blue dopant.

8. The organic light emitting diode according to claim 7, wherein a difference between the triplet energy of the second hole auxiliary layer and the triplet energy of the fourth blue dopant is 0.2 eV or more.

9. The organic light emitting diode according to claim 7, wherein a triplet energy of the fourth blue host is smaller than the triplet energy of the fourth blue dopant and greater than a triplet energy of the fifth blue host.

10. The organic light emitting diode according to claim 1, further comprising:
a third emitting stack positioned between the first charge generation layer and the second emitting stack, wherein the third emitting stack includes a third emitting material layer; and
a second charge generation layer positioned between the second emitting stack and the third emitting stack.

11. The organic light emitting diode according to claim 10, wherein the third emitting material layer includes a red emitting layer and a green emitting layer.

12. The organic light emitting diode according to claim 10, wherein the third emitting material layer includes a yellow-green emitting layer.

13. The organic light emitting diode according to claim 1, further comprising:
a third emitting stack positioned between the second emitting stack and the second electrode, and including (i) a third hole transporting layer, (ii) a third hole auxiliary layer on the third hole transporting layer, and (iii) a third emitting material layer on the third hole auxiliary layer;
a fourth emitting stack positioned between the third emitting stack and the second electrode and including a fourth emitting material layer;
a second charge generation layer between the second emitting stack and the third emitting stack; and
a third charge generation layer between the third emitting stack and the fourth emitting stack.

14. The organic light emitting diode according to claim 13, wherein each of the first emitting material layer, the second emitting material layer, and the third emitting material layer is a blue emitting material layer, and
wherein the fourth emitting material layer is a green emitting material layer.

15. The organic light emitting diode according to claim 13, wherein a hole mobility of the third hole transporting layer is greater than a hole mobility of the third hole auxiliary layer, and
wherein the hole mobility of the third hole auxiliary layer is greater than the hole mobility of the first hole auxiliary layer and greater than the hole mobility of the second hole auxiliary layer.

16. An organic light emitting display device, comprising:
a substrate;
an organic light emitting diode according to claim 1 disposed over the substrate; and
an encapsulation layer covering the organic light emitting diode.

17. The organic light emitting display device according to claim 16, further comprising:
a color filter layer disposed over the organic light emitting diode,
wherein the color filter layer corresponds to a red pixel region, a green pixel region, and a blue pixel region.

18. The organic light emitting display device according to claim 17, further comprising:
a color conversion layer disposed between the color filter layer in the red pixel region and the organic light emitting diode in the red pixel region, and disposed between the color filter layer in the green pixel region and the organic light emitting diode in the green pixel region.

19. The organic light emitting display device according to claim 16, wherein the first blue emitting layer includes a first blue host and a first blue dopant,
wherein the second blue emitting layer includes a second blue host and a second blue dopant,
wherein the third blue emitting layer includes a third blue host and a third blue dopant,
wherein the fourth blue emitting layer includes a fourth blue host and a fourth blue dopant,
wherein the fifth blue emitting layer includes a fifth blue host and a fifth blue dopant, and
wherein the sixth blue emitting layer includes a sixth blue host and a sixth blue dopant.

20. The organic light emitting display device according to claim 19, wherein a triplet energy of the first hole auxiliary layer is greater than a triplet energy of the first blue dopant, and
wherein a triplet energy of the first blue host is smaller than the triplet energy of the first blue dopant and greater than a triplet energy of the second blue host.

21. The organic light emitting display device according to claim 16, further comprising:
a third emitting stack positioned between the first charge generation layer and the second emitting stack, and including a third emitting material layer; and
a second charge generation layer positioned between the second emitting stack and the third emitting stack.

22. The organic light emitting display device according to claim 16, further comprising:
a third emitting stack positioned between the second emitting stack and the second electrode, and including (i) a third hole transporting layer, (ii) a third hole auxiliary layer on the third hole transporting layer, and (iii) a third emitting material layer on the third hole auxiliary layer;
a fourth emitting stack positioned between the third emitting stack and the second electrode, and including a fourth emitting material layer;
a second charge generation layer between the second emitting stack and the third emitting stack; and
a third charge generation layer between the third emitting stack and the fourth emitting stack.
